(19) United States
(12) Patent Application Publication
(10) Pub. No.: US 2025/0062265 A1
(43) Pub. Date: Feb. 20, 2025

(54) SEMICONDUCTOR PACKAGE AND MANUFACTURING METHOD THEREOF

(71) Applicant: Orient Semiconductor Electronics, Limited, Kaohsiung City (TW)

(72) Inventors: YUEH-MING TUNG, Kaohsiung City (TW); Chia-Ming Yang, Kaohsiung City (TW); Tsun-Lung Hsieh, Kaohsiung City (TW); Ying-Chih Lee, Kaohsiung City (TW)

(21) Appl. No.: 18/605,859

(22) Filed: Mar. 15, 2024

(30) Foreign Application Priority Data
Aug. 14, 2023 (TW) 112130494

(51) Int. Cl. H01L 23/00; H01L 23/31; H01L 25/00; H01L 25/065

(52) U.S. Cl. CPC H01L 24/19; H01L 23/3128; H01L 24/20; H01L 25/0655; H01L 25/50; H01L 2224/19; H01L 2224/214; H01L 2224/215; H01L 2924/01029; H01L 2924/01079

(57) ABSTRACT

The present disclosure provides a semiconductor package. The semiconductor package includes a heat spreader, a first die, a plurality of first conductive bumps, a molding layer and a redistribution layer. The first die is disposed on the heat spreader and has a top surface and a bottom surface opposing to the top surface. The first conductive bumps are disposed on the top surface of the first die and electrically connected to the first die. The molding layer is formed on the heat spreader to cover the top surface of the first die and expose the first conductive bumps. The redistribution layer is disposed on the molding layer to electrically connect to the first conductive bumps. The present disclosure further provides a method of manufacturing the above semiconductor package.

### CROSS-REFERENCE TO RELATED APPLICATIONS

The present application is based on and claims priority to Taiwanese Application Number 112130494, filed Aug. 14, 2023, the disclosure of which is hereby incorporated by reference herein in its entirety.

### FIELD OF THE DISCLOSURE

This disclosure relates to a semiconductor package and a manufacturing method thereof, and more particularly relates to a semiconductor package having a heat spreader, and a manufacturing method thereof.

### BACKGROUND OF THE DISCLOSURE

Existing semiconductor package structures made by flip die technology are usually not thin enough to meet the thinning requirements. With the demand for more sophisticated and smaller chips and packaging, the development of semiconductors towards fan-out packaging is an inevitable path.

In the current fan-out package with a heat spreader, the heat spreader is always attached to the molding material that seals the die. When the heat generated by the die needs to be dissipated, it is first transferred to the molding material and then to the heat spreader before it dissipates. This reduces the efficiency of heat dissipation.

### SUMMARY

In view of the above, the present disclosure provides a semiconductor package and a manufacturing method thereof, wherein a redistribution process is used to reduce the overall thickness of the semiconductor package, and a heat spreader is equipped to increase heat dissipation efficiency.

In one embodiment, the semiconductor package of the present disclosure includes a heat spreader, a first die, a plurality of first conductive bumps, a molding layer and a redistribution layer. The first die is disposed on the heat spreader and has a top surface and a bottom surface opposing to the top surface. The first conductive bumps are disposed on the top surface of the first die and electrically connected to the first die. The molding layer is formed on the heat spreader to cover the top surface of the first die and expose the first conductive bumps. The redistribution layer is disposed on the molding layer to electrically connect to the first conductive bumps. The present disclosure further provides a method of manufacturing the above semiconductor package.

In one embodiment, the method of manufacturing a semiconductor package comprises: providing a first die having opposing top surface and bottom surface; forming a plurality of first conductive bumps on the top surface of the first die, wherein the first conductive bumps are electrically connected to the first die; adhering the first die to a heat spreader; forming a molding layer on the heat spreader to cover the first conductive bumps and the first die; grinding the molding layer to expose the first conductive bumps; and forming a redistribution layer on the molding layer to electrically connect to the first conductive bumps.

In the semiconductor package of the present disclosure, a redistribution process is used to reduce the overall thickness of the semiconductor package to less than 0.15 mm, and a heat spreader is provided on the bottom surface of the die to increase heat dissipation efficiency.

The foregoing, as well as additional objects, features and advantages of the disclosure will be more readily apparent from the following detailed description, which proceeds with reference to the accompanying drawings.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of the semiconductor package of the present disclosure.

FIGS. 2 to 9 illustrate the method of manufacturing the semiconductor package of FIG. 1.

### DETAILED DESCRIPTION OF THE DISCLOSURE

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatial relative terms, such as “beneath.” “below,” “lower,” “above,” “upper” and the like, may be used herein for ease of description to describe one element or feature's relationship to another element(s) or feature(s) as illustrated in the figures. The spatial relative terms are intended to encompass different orientations of the device in use or operation in addition to the orientation depicted in the figures. The apparatus may be otherwise oriented (rotated 90 degrees or at other orientations) and the spatial relative descriptors used herein may likewise be interpreted accordingly.

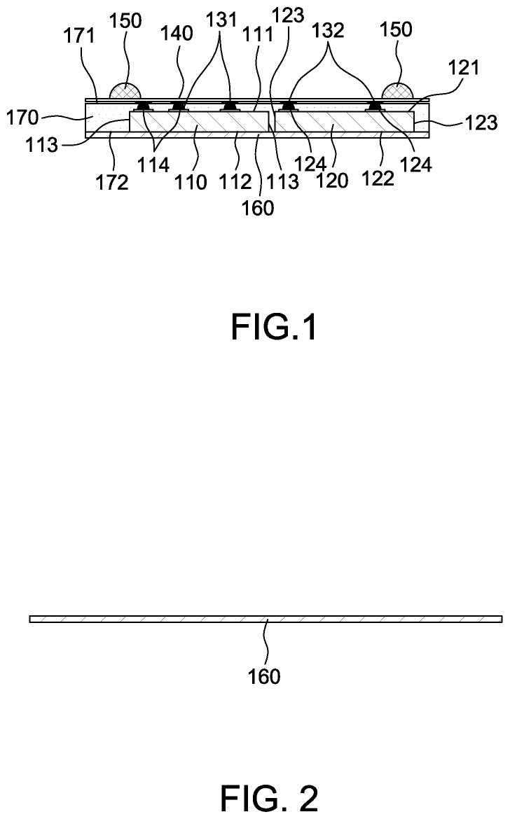

Referring to FIG. 1, the semiconductor package of the present disclosure includes a heat spreader 160 made of copper or other thermally conductive materials. In the present disclosure, the heat spreader 160 may be constructed of a lead frame. One or more dies are attached to the heat spreader 160, for example, a first die 110 and a second die 120, wherein the first die 110 and the second die 120 are arranged side by side.

The first die 110 has a first surface 111, a second surface 112, and a plurality of third surfaces 113, wherein the first surface 111 is an active surface. The first surface 111 and the second surface 112 are located on different planes. The third surfaces 113 connect the first surface 111 and the second surface 112. A plurality of first bonding pads 114 is formed on the first surface 111. In one embodiment, the first surface 111 is a top surface, the second surface 112 is a bottom surface, and the third surfaces 113 are side surfaces, but is not limited thereto.

The second die 120 has a first surface 121, a second surface 122, and a plurality of third surfaces 123, wherein the first surface 121 is an active surface. The first surface 121 and the second surface 122 are located on different planes. The third surfaces 123 connect the first surface 121 and the second surface 122. A plurality of second bonding pads 124 is formed on the first surface 121. In one embodiment, the first surface 121 is a top surface, the second surface 122 is a bottom surface, and the third surfaces 123 are side surfaces, but is not limited thereto.

A plurality of first conductive bumps 131 is respectively provided on the first bonding pads 114 on the first surface 111 of the first die 110, and is electrically connected to the first die 110 through the first bonding pads 114. A plurality of second conductive bumps 132 is respectively provided on the second bonding pads 124 on the first surface 121 of the second die 120, and is electrically connected to the second die 120 through the second bonding pads 124. The first conductive bumps 131 and the second conductive bumps 132 are made of conductive materials. In one embodiment, the first conductive bumps 131 and the second conductive bumps 132 may be made of gold, copper or alloys. For example, the first conductive bumps 131 and the second conductive bumps 132 may be respectively formed on the first bonding pads 114 of the first die 110 and the second bonding pads 124 of the second die 120 through a wire bonding process using gold wires, copper wires, alloy wires, or other conductive wires. In another embodiment, the first conductive bumps 131 and the second conductive bumps 132 are metal bumps, formed by a bumping process. The first conductive bumps 131 and the second conductive bumps 132 may be composed of eutectic, lead free, high lead materials, or copper pillars. In one embodiment, the first conductive bumps 131 and the second conductive bumps 132 may be spherical or ball-shaped.

A molding layer 170 is formed on the heat spreader 160. The molding layer 170 is made of a molding material, such as epoxy resin, but is not limited thereto. The molding layer 170 has a first surface 171 and a second surface 172 opposing to the first surface 171. The first surface 171 and the second surface 172 are located on different planes. For example, the first surface 171 is a top surface and the second surface 172 is a bottom surface. The molding layer 170 is further formed on the first surface 111 of the first die 110 and the first surface 121 of the second die 120, and covers the third surfaces 113 of the first die 110 and the third surfaces 123 of the second die 120. The molding layer 170 is not formed on the second surface 112 of the first die 110 and the second surface 122 of the second die 120, and does not completely cover the first conductive bumps 131 and the second conductive bumps 132. Each of the first conductive bumps 131 and the second conductive bumps 132 is partially exposed from the molding layer 170. Therefore, the first surface 171 of the molding layer 170 is located above the first surface 111 of the first die 110 and the first surface 121 of the second die 120, and the second surface 172 of the molding layer 170 is flush with the second surface 112 of the first die 110 and the second surface 122 of the second die 120.

A redistribution layer (RDL) 140 is formed on the first surface 171 of the molding layer 170. The redistribution layer 140 has conductive traces formed therein. The redistribution layer 140 extends from above the first surface 111 of the first die 110 to above the first surface 121 of the second die 120, and is connected with the first conductive bumps 131 and the second conductive bumps 132. The first die 110 is electrically connected to the second die 120 through the redistribution layer 140.

A plurality of solder balls 150 is disposed on the redistribution layer 140. The solder balls 150 are electrically connected to the redistribution layer 140. The first die 110 and the second die 120 may be electrically connected to an external circuit through the redistribution layer 140 using the solder balls 150.

Referring to FIGS. 2 to 9, wherein FIGS. 2, 3-1, 4-1, and 5 to 9 illustrate a method of manufacturing the semiconductor package of FIG. 1 according to the first embodiment of the present disclosure. FIGS. 2, 3-2, 4-2, and 5 to 9 illustrate another method of manufacturing the semiconductor package of FIG. 1 according to the second embodiment of the present disclosure.

The method of manufacturing the semiconductor package of FIG. 1 according to the first embodiment of the present disclosure is first described in detail below.

As shown in FIG. 2, a heat spreader 160 is provided. The heat spreader 160 may be made of copper or other thermally conductive materials. In the present disclosure, the heat spreader 160 may be constructed of a lead frame.

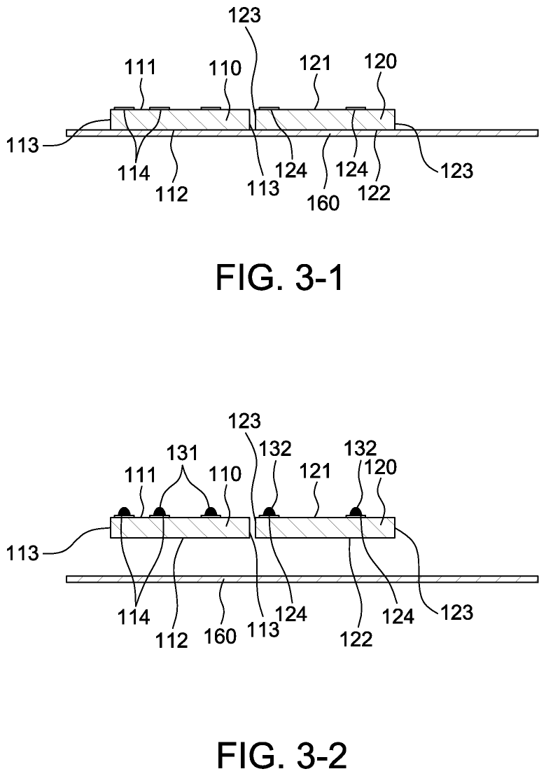

As shown in FIG. 3-1, one or more dies, such as a first die 110 and a second die 120 are adhered to the heat spreader 160, wherein the first die 110 and the second die 120 are arranged side by side.

The first die 110 has a first surface 111, a second surface 112, and a plurality of third surfaces 113, wherein the first surface 111 is an active surface and the second surface 112 is adhered to the heat spreader 160. The first surface 111 and the second surface 112 are located on different planes. The third surfaces 113 connect the first surface 111 and the second surface 112. The first surface 111 is formed with a plurality of first bonding pads 114 thereon. In one embodiment, the first surface 111 is a top surface, the second surface 112 is a bottom surface, and the third surfaces 113 are side surfaces, but is not limited thereto.

The second die 120 has a first surface 121, a second surface 122, and a plurality of third surfaces 123, wherein the first surface 121 is an active surface and the second surface 122 is adhered to the heat spreader 160. The first surface 121 and the second surface 122 are located on different planes. The third surfaces 123 connect the first surface 121 and the second surface 122. The first surface 121 is formed with a plurality of second bonding pads 124. In one embodiment, the first surface 121 is a top surface, the second surface 122 is a bottom surface, and the third surfaces 123 are side surfaces, but is not limited thereto.

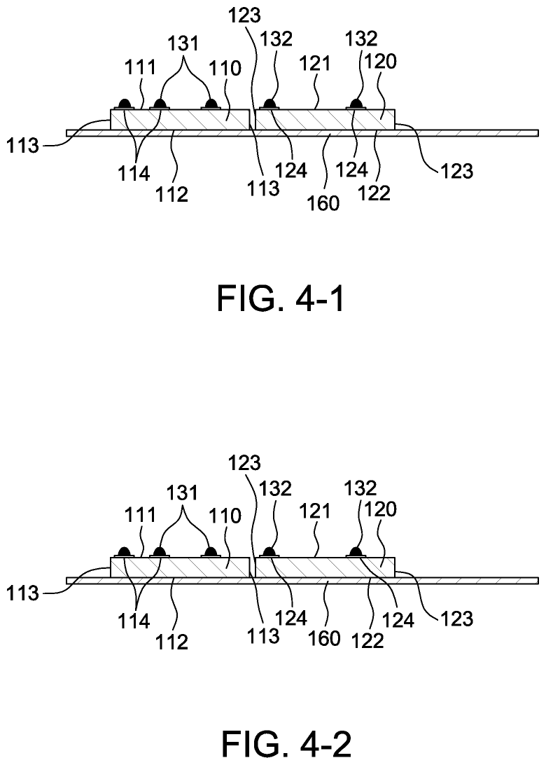

As shown in FIG. 4-1, a plurality of first conductive bumps 131 is then disposed on the first bonding pads 114 on the first surface 111 of the first die 110. A plurality of second conductive bumps 132 is disposed on the second bonding pads 124 on the first surface 121 of the second die 120. The first conductive bumps 131 are electrically connected to the first die 110 through the first bonding pads 114 and the second conductive bumps 132 are electrically connected to the second die 120 through the second bonding pads 124.

The first conductive bumps 131 and the second conductive bumps 132 are made of conductive materials, such as gold, copper or alloys. In this embodiment, the first conductive bumps 131 and the second conductive bumps 132 may be respectively formed on the first bonding pads 114 of the first die 110 and the second bonding pads 124 of the second die 120 through a wire bonding process using gold wires, copper wires, alloy wires, or other conductive wires.

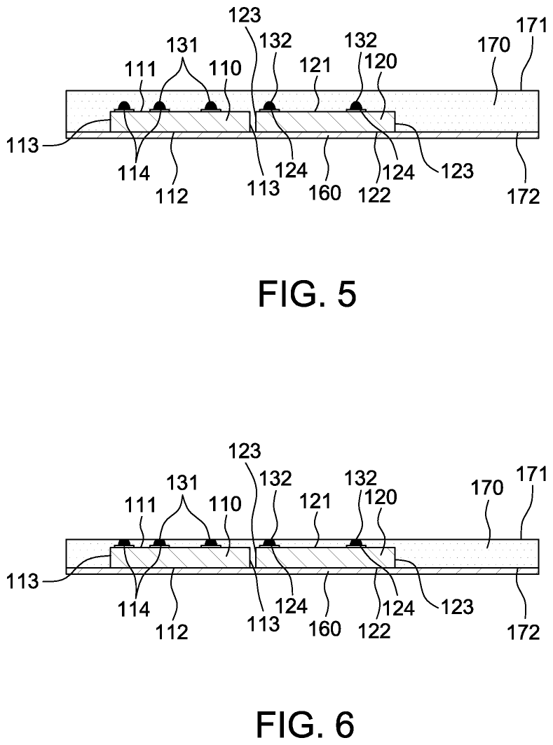

As shown in FIG. 5, a molding layer 170 covering the first conductive bumps 131 and the second conductive bumps 132 is then formed on the heat spreader 160 using an adhesive material, such as epoxy resin. The molding layer 170 has a first surface 171 and a second surface 172 opposing to the first surface 171. The first surface 171 and the second surface 172 are located on different planes. For example, the first surface 171 is a top surface and the second surface 172 is a bottom surface. The molding layer 170 is further formed on the first surface 111 of the first die 110 and the first surface 121 of the second die 120, and covers the third surfaces 113 of the first die 110 and the third surfaces 123 of the second die 120. The molding layer 170 is not formed on the second surface 112 of the first die 110 and the second surface 122 of the second die 120 since it is obscured by the heat spreader 160. The second surface 172 of the molding layer 170 is flush with the second surface 112 of the first die 110 and the second surface 122 of the second die 120.

As shown in FIG. 6, the first surface 171 of the molding layer 170 is then ground to reduce the thickness of the molding layer 170 so that tops of the first conductive bumps 131 and the second conductive bumps 132 are exposed.

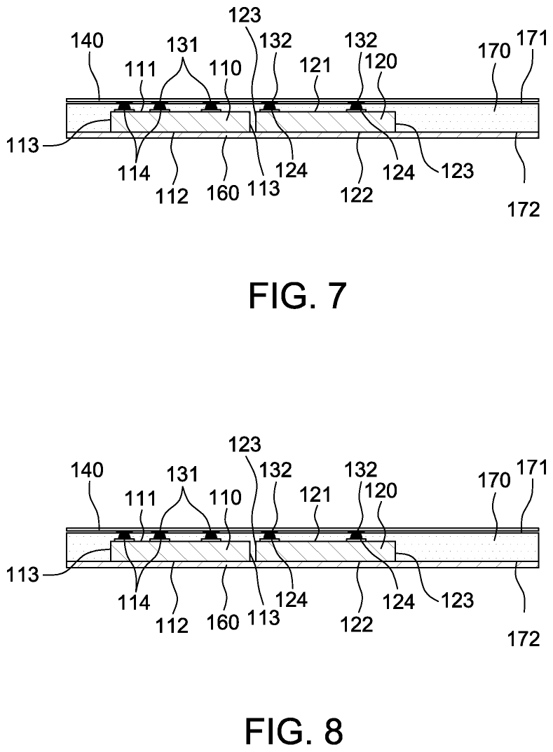

As shown in FIG. 7, a redistribution layer 140 with conductive traces therein is subsequently formed on the first surface 171 of the molding layer 170 by a redistribution process. The redistribution layer 140 extends from above the first surface 111 of the first die 110 to above the first surface 121 of the second die 120, and is connected with the first conductive bumps 131 and the second conductive bumps 132. The first die 110 is electrically connected to the second die 120 through the redistribution layer 140.

As shown in FIG. 8, the first conductive bumps 131 and the second conductive bumps 132 are then wire-redistributed to generate contacts used for electrical connection to an external circuit.

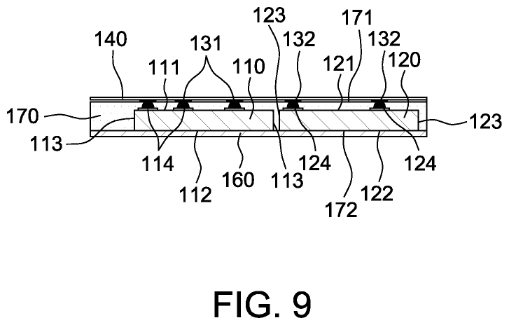

As shown in FIG. 9, the molding layer 170 and the heat spreader 160 are then divided, and a plurality of solder balls 150 are formed on and electrically to the redistribution layer 140 so as to form a plurality of semiconductor packages of FIG. 1.

The method of manufacturing the semiconductor package of FIG. 1 according to the second embodiment of the present disclosure also includes the steps shown in FIGS. 2 and 5 to 9 in the first embodiment, where the same reference numerals represent the same or similar elements. In the second embodiment, after implementing the steps shown in FIG. 2, the steps shown in FIGS. 3-2, 4-2, and 5 to 9 are then implemented in sequence.

As shown in FIG. 3-2, before the first die 110 and the second die 120 are adhered to the heat spreader 160, the first conductive bumps 131 and the second conductive bumps 132 have been formed by a bumping process on the first bonding pads 114 of the first die 110 and the second bonding pads 124 of the second die 120 respectively. The first conductive bumps 131 and the second conductive bumps 132 may be composed from eutectic, lead free, high lead materials, or copper pillars.

The first die 110 and the second die 120 are then adhered to the heat spreader 160 to form the structure shown in FIG. 4-2.

After the steps shown in FIG. 4-2 are implemented, the steps shown in FIGS. 5 to 9 are implemented sequentially to obtain the semiconductor package shown in FIG. 1. The steps shown in FIGS. 5 to 9 have been described in detail above and will not be repeated herein.

In the semiconductor package of the present disclosure, a redistribution process is used to reduce the overall thickness of the semiconductor package to less than 0.15 mm, and a heat spreader is provided on the bottom surface of the die to increase heat dissipation efficiency.

Although the preferred embodiments of the disclosure have been disclosed for illustrative purposes, those skilled in the art will appreciate that various modifications, additions and substitutions are possible, without departing from the scope and spirit of the disclosure as disclosed in the accompanying claims.

1. A method of manufacturing a semiconductor package, comprising:
providing a first die having opposing top surface and bottom surface;
forming a plurality of first conductive bumps on the top surface of the first die, wherein the first conductive bumps are electrically connected to the first die;
adhering the first die to a heat spreader;
forming a molding layer on the heat spreader to cover the first conductive bumps and the first die;
grinding the molding layer to expose the first conductive bumps; and
forming a redistribution layer on the molding layer to electrically connect to the first conductive bumps.

2. The method as claimed in claim 1, further comprising:
providing a second die having opposing top surface and bottom surface;
forming a plurality of second conductive bumps on the top surface of the second die, wherein the second conductive bumps are electrically connected to the second die;
adhering the second die to the heat spreader;
covering the second conductive bumps and the second die with the molding layer;
exposing the second conductive bumps from the molding layer; and
electrically connecting the redistribution layer to the second conductive bumps.

3. The method as claimed in claim 1, wherein the heat spreader is a lead frame.

4. The method as claimed in claim 1, wherein the first conductive bumps are formed on the first die by a wire bonding process using one of gold wires, copper wires and alloy wires.

5. The method as claimed in claim 4, wherein the first conductive bumps are formed on the first die after the first die is adhered to the heat spreader.

6. The method as claimed in claim 1, wherein the first conductive bumps are formed on the first die by a bumping process.

7. The method as claimed in claim 6, wherein the first die is adhered to the heat spreader after the first conductive bumps are formed on the first die.

8. A semiconductor package, comprising:
a heat spreader;
a first die disposed on the heat spreader, the first die having opposing top surface and bottom surface;
a plurality of first conductive bumps disposed on the top surface of the first die, wherein the first conductive bumps are electrically connected to the first die;
a molding layer formed on the heat spreader to cover the top surface of the first die and expose the first conductive bumps; and
a redistribution layer disposed on the molding layer to electrically connect to the first conductive bumps.

9. The semiconductor package as claimed in claim 8, further comprising:
a second die disposed on the heat spreader, the second die having opposing top surface and bottom surface; and
a plurality of second conductive bumps disposed on the top surface of the second die, wherein the second conductive bumps are electrically connected to the second die;
wherein
the molding layer further covers the top surface of the second die and exposes the second conductive bumps; and
the redistribution layer is further electrically connected to the second conductive bumps.

10. The semiconductor package as claimed in claim 8, wherein the heat spreader is a lead frame.
